(19) United States
(12) Patent Application Publication
(10) Pub. No.: US 2015/0069497 A1
(43) Pub. Date: Mar. 12, 2015

(54) NONVOLATILE SEMICONDUCTOR MEMORY DEVICE AND METHOD FOR MANUFACTURING SAME

(71) Applicant: Kabushiki Kaisha Toshiba, Minato-ku (JP)

(72) Inventor: Kiyohito NISHIHARA, Mie-ken (JP)

(73) Assignee: Kabushiki Kaisha Toshiba, Minato-ku (JP)

(21) Appl. No.: 14/191,844

(22) Filed: Feb. 27, 2014

Related U.S. Application Data
(60) Provisional application No. 61/876,256, filed on Sep. 11, 2013.

(51) Int. Cl. H01L 29/792; H01L 21/28

(52) U.S. Cl. CPC H01L 29/792; H01L 21/28282
USPC 257/324; 438/586

(57) ABSTRACT

According to one embodiment, a nonvolatile semiconductor memory device, includes: control gate electrodes provided above semiconductor regions; a charge accumulation layer; a first insulating film; a second insulating film; a select gate electrode; a conductive structural body located on opposite side of the select gate electrode from the plurality of control gate electrodes, the conductive structural body provided on each of the plurality of semiconductor regions, and the conductive structural body including a fourth insulating film, a semiconductor-containing layer provided on the fourth insulating film, and a conductive film in contact with a sidewall of the fourth insulating film and a sidewall of the semiconductor-containing layer; and a contact electrode extending in a third direction from a side of the plurality of semiconductor regions to a side of the plurality of control gate electrodes, and the contact electrode connected to the conductive structural body.

### CROSS-REFERENCE TO RELATED APPLICATIONS

This application is based upon and claims the benefit of priority from U.S. Provisional Patent Application 61/876,256 filed on Sep. 11, 2013; the entire contents of which are incorporated herein by reference.

### FIELD

Embodiments described herein relate generally to a nonvolatile semiconductor memory device and a method for manufacturing the same.

### BACKGROUND

In a nonvolatile semiconductor memory device in which a plurality of NAND memory strings are arranged, the spacing between the plurality of NAND memory strings becomes narrower and narrower with its miniaturization. This increases the possibility of short circuit between the adjacent NAND memory strings through the contact connected to the active region of the NAND memory strings.

Such short circuit can be avoided by the method of narrowing the line width of the contact connected to the active region. However, this method incurs open failure between the active region and the contact, and the increase of contact resistance between the active region and the contact.

### BRIEF DESCRIPTION OF THE DRAWINGS

FIG. 1 is a schematic plan view showing a nonvolatile semiconductor memory device according to the present embodiment;

FIG. 2A is a schematic sectional view at the position of line A-A′ of FIG. 1, FIG. 2B is a schematic sectional view at the position of line B-B′ of FIG. 1;

FIG. 3 is a schematic plan view showing a process for manufacturing a nonvolatile semiconductor memory device according to this embodiment; and

FIGS. 4A to 13 are schematic sectional views showing the process for manufacturing a nonvolatile semiconductor memory device according to this embodiment.

### DETAILED DESCRIPTION

In general, according to one embodiment, a nonvolatile semiconductor memory device, includes: a plurality of semiconductor regions extending in a first direction and arranged in a second direction crossing the first direction; a plurality of control gate electrodes provided above the plurality of semiconductor regions, the control gate electrodes extending in the second direction, and the control gate electrodes arranged in the first direction; a charge accumulation layer provided at a crossing position of each of the plurality of semiconductor regions and each of the plurality of control gate electrodes; a first insulating film provided between the charge accumulation layer and each of the plurality of semiconductor regions; a second insulating film provided between the charge accumulation layer and each of the plurality of control gate electrodes; a select gate electrode provided on the plurality of semiconductor regions via a third insulating film, the select gate electrode extending in the second direction, and the select gate electrode located at an end of the arranged plurality of control gate electrodes; a conductive structural body located on opposite side of the select gate electrode from the plurality of control gate electrodes, the conductive structural body provided on each of the plurality of semiconductor regions, and the conductive structural body including a fourth insulating film, a semiconductor-containing layer provided on the fourth insulating film, and a conductive film in contact with a sidewall of the fourth insulating film and a sidewall of the semiconductor-containing layer; and a contact electrode extending in a third direction from a side of the plurality of semiconductor regions to a side of the plurality of control gate electrodes, and the contact electrode connected to the conductive structural body.

Embodiments will now be described with reference to the drawings. In the following description, like members are labeled with like reference numerals. The description of the members once described is omitted appropriately.

### Embodiment

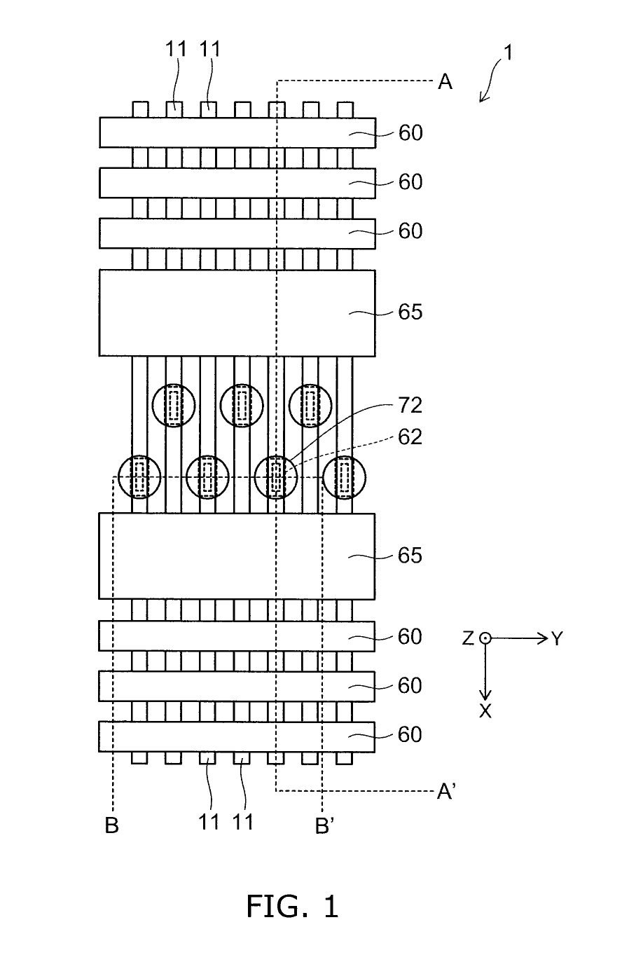

FIG. 1 is a schematic plan view showing a nonvolatile semiconductor memory device according to the present embodiment.

The nonvolatile semiconductor memory device 1 according to this embodiment includes a NAND flash memory.

The nonvolatile semiconductor memory device 1 includes a semiconductor region 11, a control gate electrode 60, a charge accumulation layer 30, a select gate electrode 65, a conductive structural body 62, and a contact electrode 72.

For instance, as shown in FIG. 1, in the nonvolatile semiconductor memory device 1, a plurality of semiconductor regions 11 extend in the X-direction (first direction) and are arranged in the Y-direction (second direction) crossing the X-direction. Above the plurality of semiconductor regions 11, a plurality of control gate electrodes 60 are provided. The plurality of control gate electrodes 60 extend in the Y-direction and are arranged in the X-direction. At the end of the arranged plurality of control gate electrodes 60, the select gate electrode 65 is arranged. The select gate electrode 65 extends in the Y-direction.

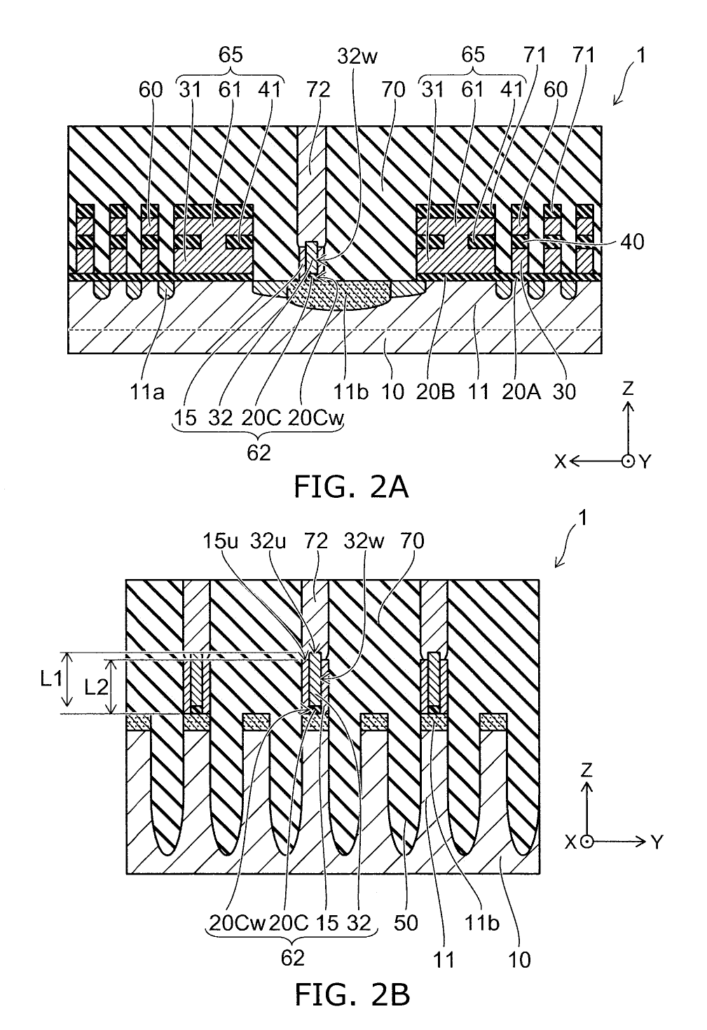

FIG. 2A is a schematic sectional view at the position of line A-A′ of FIG. 1. FIG. 2B is a schematic sectional view at the position of line B-B′ of FIG. 1.

FIGS. 2A and 2B show cross sections near the select gate electrode of the NAND string.

For instance, as shown in FIGS. 2A and 2B, the plurality of semiconductor regions 11 are regions formed from a semiconductor layer 10 separated by element separating regions 50. The semiconductor region 11 is an active region occupied by a transistor of the nonvolatile semiconductor memory device 1. The semiconductor region 11 is e.g. a p-type semiconductor region.

As shown in FIG. 2A, on the semiconductor region 11, a gate insulating film 20A (first insulating film) is provided. The gate insulating film 20A is provided between the charge accumulation layer 30 and each of the plurality of semiconductor regions 11. The gate insulating film 20A can tunnel charge (e.g., electrons) between the semiconductor region 11 and the charge accumulation layer 30.

Furthermore, as shown in FIG. 2A, the charge accumulation layer 30 is provided at the crossing position of each of the plurality of semiconductor regions 11 and each of the plurality of control gate electrodes 60. The charge accumulation layer 30 is provided on the gate insulating film 20A. The charge accumulation layer 30 can accumulate the charge tunneled from the semiconductor region 11 via the gate insulating film 20A. In the following description, the charge accumulation layer 30 is assumed to have a structure based on a floating gate. However, the charge accumulation layer 30 is not limited to the floating gate, but may be a silicon nitride film in a MONOS structure as described later.

Between the charge accumulation layer 30 and each of the plurality of control gate electrodes 60, an IPD (inter-poly dielectric) film 40 (second insulating film) is provided. The control gate electrode 60 covers the charge accumulation layer 30 via the IPD film 40. The control gate electrode 60 functions as a gate electrode for writing charge to the charge accumulation layer 30 and reading the charge written in the charge accumulation layer 30.

The stacked body including the charge accumulation layer 30, the IPD film 40, and the control gate electrode 60 is referred as memory cell.

At the end of the arranged plurality of control gate electrodes 60, the select gate electrode 65 is provided. The select gate electrode 65 is provided on the semiconductor region 11 via a gate insulating film 20B (third insulating film). The select gate electrode 65 includes a semiconductor-containing layer 31, a metal-containing layer 61, and an insulating film 41 sandwiched between the semiconductor-containing layer 31 and the metal-containing layer 61.

Furthermore, as shown in FIGS. 2A and 2B, on the opposite side of the select gate electrode 65 from the plurality of control gate electrodes 60, the conductive structural body 62 is provided. The conductive structural body 62 may be referred to as conductive connector. The conductive structural body 62 is provided on each of the plurality of semiconductor regions 11. The conductive structural body 62 includes an insulating film 20C (fourth insulating film), a semiconductor-containing layer 32 provided on the insulating film 20C, and a conductive film 15 in contact with the sidewall 20Cw of the insulating film 20C and the sidewall 32w of the semiconductor-containing layer 32. The conductive film 15 has a tubular structure.

The contact electrode 72 extends in the Z-direction (third direction) from the side of the plurality of semiconductor regions 11 toward the side of the plurality of control gate electrodes 60. The contact electrode 72 is connected to the conductive structural body 62.

Furthermore, between the adjacent charge accumulation layers 30 and between the charge accumulation layer 30 and the select gate electrode 65, the upper side of the semiconductor region 11 constitutes a diffusion region (source/drain region) 11a doped with n-type impurity. The region of the semiconductor region 11 below the conductive structural body 62 is also doped with n-type impurity and constitutes a diffusion region 11b. The impurity concentration of the diffusion region 11b is higher than the impurity concentration of the diffusion region 11a.

The element separating region 50 is provided between the plurality of semiconductor regions 11. An insulating film 71 is provided on each of the plurality of control gate electrodes 60 and on the select gate electrode 65. An interlayer insulating film 70 is provided between the adjacent memory cells, between the memory cell and the select gate electrode 65, between the select gate electrode 65 and the conductive structural body 62, and between the select gate electrode 65 and the contact electrode 72. The interlayer insulating film 70 covers the memory cells and the select gate electrode 65. The length L1 from the semiconductor region 11 to the upper end 32u of the semiconductor-containing layer 32 is longer than the length L2 from the semiconductor region 11 to the upper end 15u of the conductive film 15.

The material of the semiconductor layer 10 (or semiconductor region 11) is e.g. silicon crystal. The material of the gate insulating film 20A, 20B is e.g. silicon oxide (SiOₓ) or the like. The material of the gate insulating film 20A, 20B is the same as the material of the insulating film 20C.

The IPD film 40 and the insulating film 41 may be e.g. a monolayer of silicon oxide film or silicon nitride film, or may be a stacked film of either silicon oxide film or silicon nitride film. For instance, the IPD film 40 may be what is called an ONO film (silicon oxide film/silicon nitride film/silicon oxide film).

In the case where the charge accumulation layer 30 is a floating gate layer, the material of the charge accumulation layer 30 and the semiconductor-containing layer 31 is e.g. polysilicon (poly-Si) or the like. The material of the semiconductor-containing layer 32 is the same as the material of the charge accumulation layer 30.

The material of the control gate electrode 60 and the metal-containing layer 61 is e.g. tungsten, tungsten nitride or the like.

Furthermore, in the embodiment, the material of the element separating region, the insulating film, or the insulating layer is e.g. silicon oxide (SiOx).

The conductive film 15 includes at least one of tungsten, molybdenum, tantalum, titanium, nickel, and cobalt.

The material of the contact electrode 72 is e.g. tungsten.

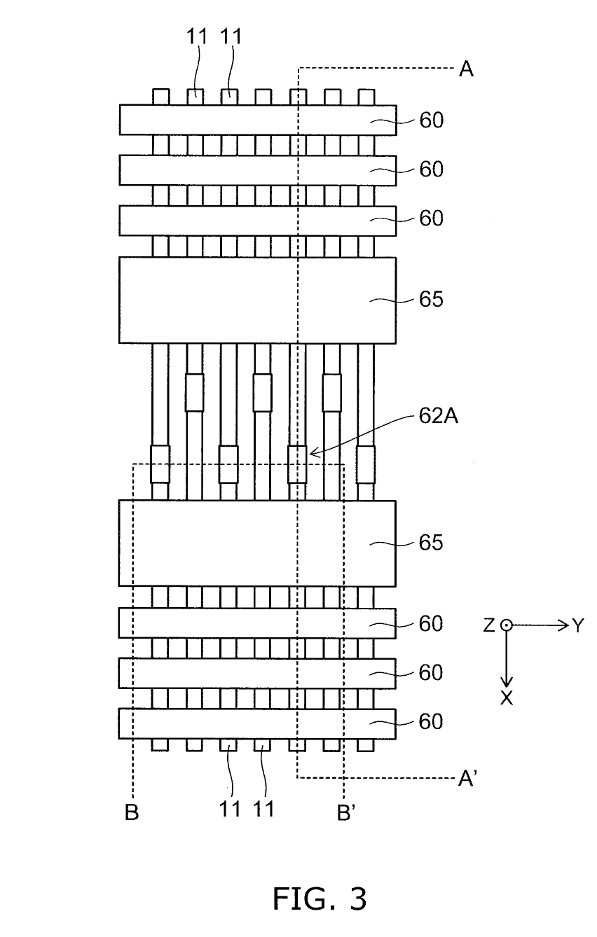

FIG. 3 is a schematic plan view showing a process for manufacturing a nonvolatile semiconductor memory device according to this embodiment.

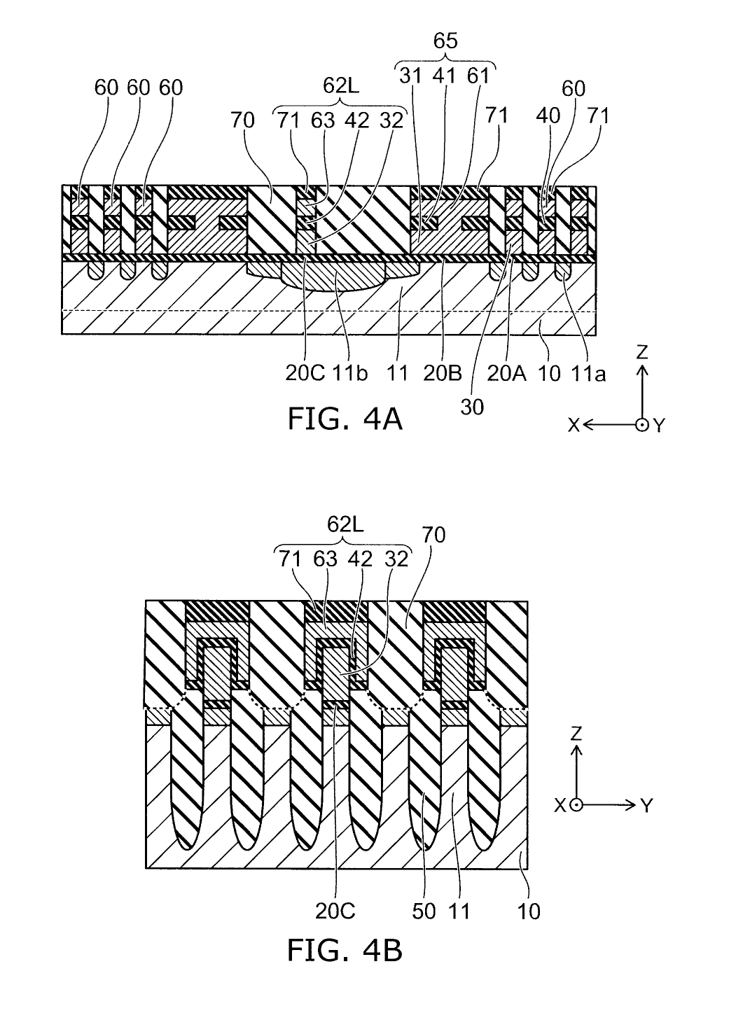

FIGS. 4A to 13 are schematic sectional views showing the process for manufacturing a nonvolatile semiconductor memory device according to this embodiment.

In FIGS. 4A to 12B, FIG. A corresponds to the A-A′ cross section of FIG. 3, and FIG. B corresponds to the B-B′ cross section of FIG. 3.

First, as shown in FIGS. 3, 4A, and 4B, a structure with memory cells and a select gate electrode 65 formed therein is prepared on the semiconductor region 11. That is, the memory cells and the select gate electrode 65 shown in FIGS. 2A and 2B are previously formed on the semiconductor region 11.

Furthermore, on the opposite side of the select gate electrode 65 from the plurality of control gate electrodes 60, a structural body 62L with a semiconductor-containing layer 32, an insulating film 42, a metal-containing layer 63, and an insulating film 71 stacked therein is previously formed on the semiconductor region 11 via an insulating film 20C.

Here, the semiconductor-containing layer 32 is formed simultaneously with the charge accumulation layer 30 at the time of forming memory cells. The insulating film 42 is formed simultaneously with the IPD film 40 at the time of forming memory cells. The metal-containing layer 63 is formed simultaneously with the control gate electrodes 60 at the time of forming memory cells. That is, after forming memory cells, the structural body 62L with the semiconductor-containing layer 32, the insulating film 42, the metal-containing layer 63, and the insulating film 71 stacked therein is left beside the select gate electrode 65. Thus, in the Y-direction, no misalignment occurs between the structural body 62L and the semiconductor region 11. At this stage, the height of the interlayer insulating film 70 is equal to the height of the insulating film 71. Furthermore, by the aforementioned simultaneous formation, the material of the semiconductor-containing layer 32 is the same as the material of the charge accumulation layer 30. The material of the insulating film 42 is the same as the material of the IPD film 40. The material of the metal-containing layer 63 is the same as the material of the control gate electrodes 60.

From the next description, without using the plan view, the sectional view is used to describe the process for manufacturing a nonvolatile semiconductor memory device according to this embodiment.

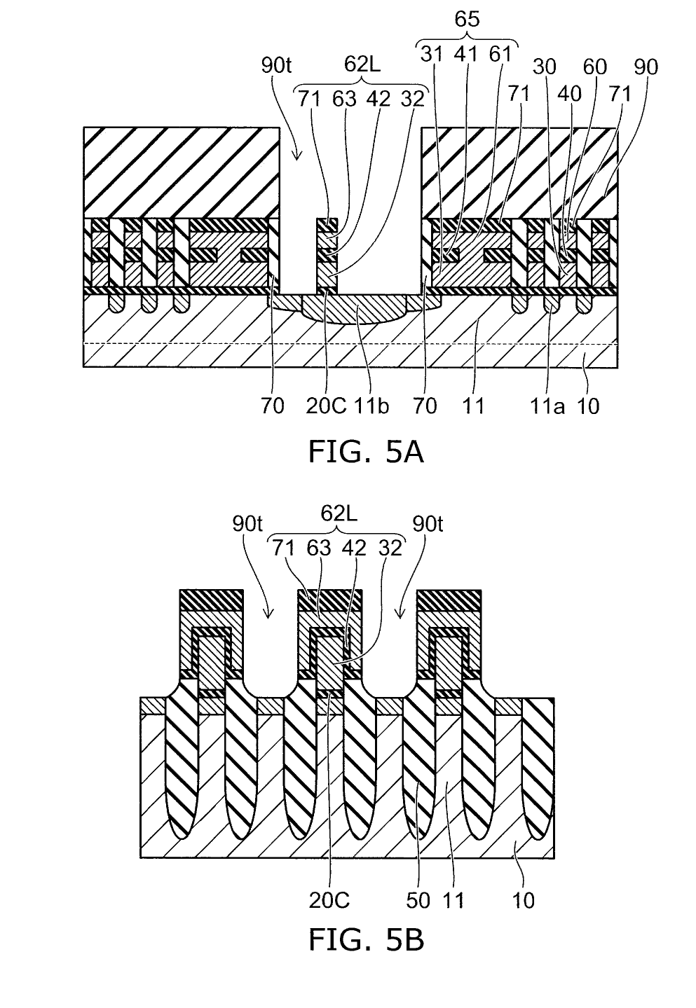

As shown in FIGS. 5A and 5B, a mask layer 90 is patterned on the control gate electrode 60, on the select gate electrode 65, and on the interlayer insulating film 70 sandwiched between the control gate electrode 60 and the select gate electrode 65. The mask layer 90 is e.g. a resist layer. Subsequently, the interlayer insulating film 70 exposed from the mask layer 90 is removed by e.g. RIE (reactive ion etching) to form a trench 90t in the mask layer 90.

After RIE, the semiconductor region 11 is exposed at the bottom of the trench 90t. However, at the time of RIE processing, the insulating film 71 functions as a mask layer. Thus, in the trench 90t, the structural body 62L including the insulating film 71, and the insulating film 20C between the structural body 62L and the semiconductor region 11 are left.

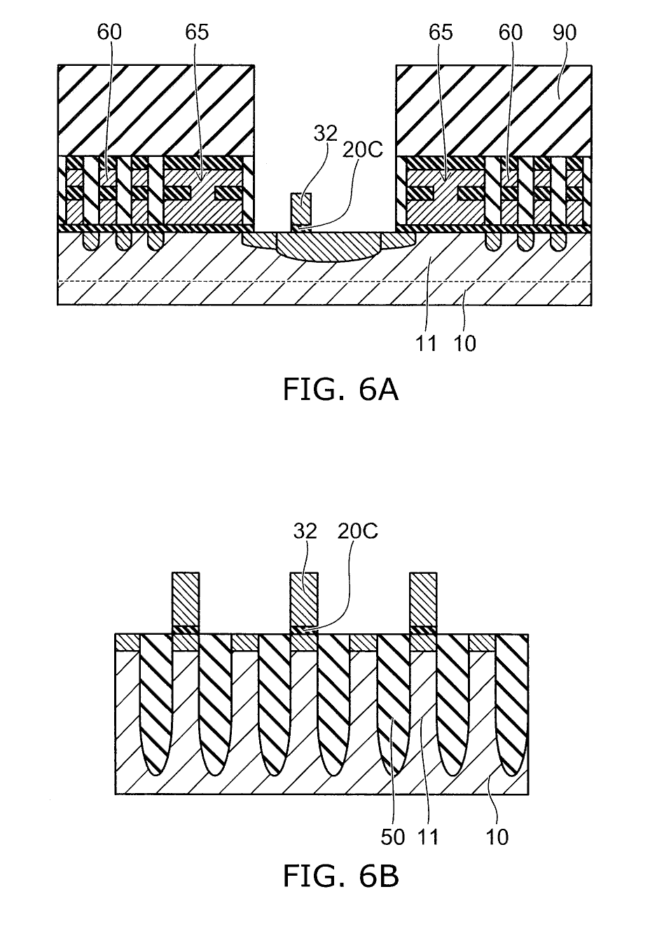

Next, as shown in FIGS. 6A and 6B, the etching condition is changed, and etching is continued. Thus, the insulating film 71, the metal-containing layer 63, and the insulating film 42 are removed from the structural body 62L. Accordingly, on the opposite side of the select gate electrode 65 from the plurality of control gate electrodes 60, the semiconductor-containing layer 32 is formed on the semiconductor region 11 via the insulating film 20C.

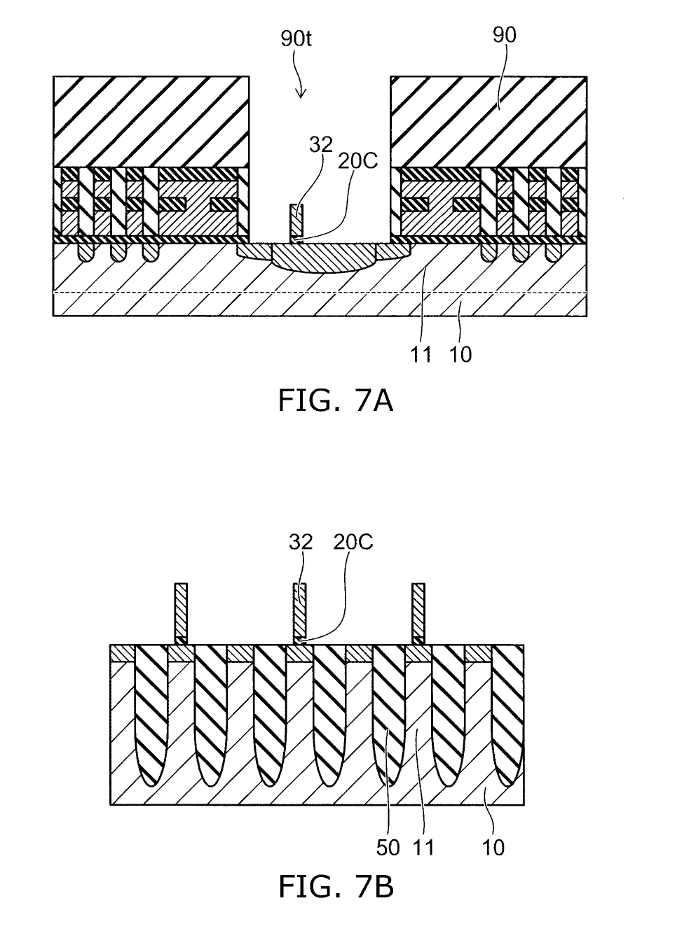

Next, as shown in FIGS. 7A and 7B, by e.g. chemical etching, the width in the X-direction and the Y-direction of the semiconductor-containing layer 32 and the insulating film 20C is reduced. For instance, the width of the semiconductor-containing layer 32 and the insulating film 20C in the Y-direction is made narrower than the width of the semiconductor region 11 in the Y-direction. Thus, in the Y-direction, the surface of the semiconductor region 11 is exposed from the semiconductor-containing layer 32 and the insulating film 20C.

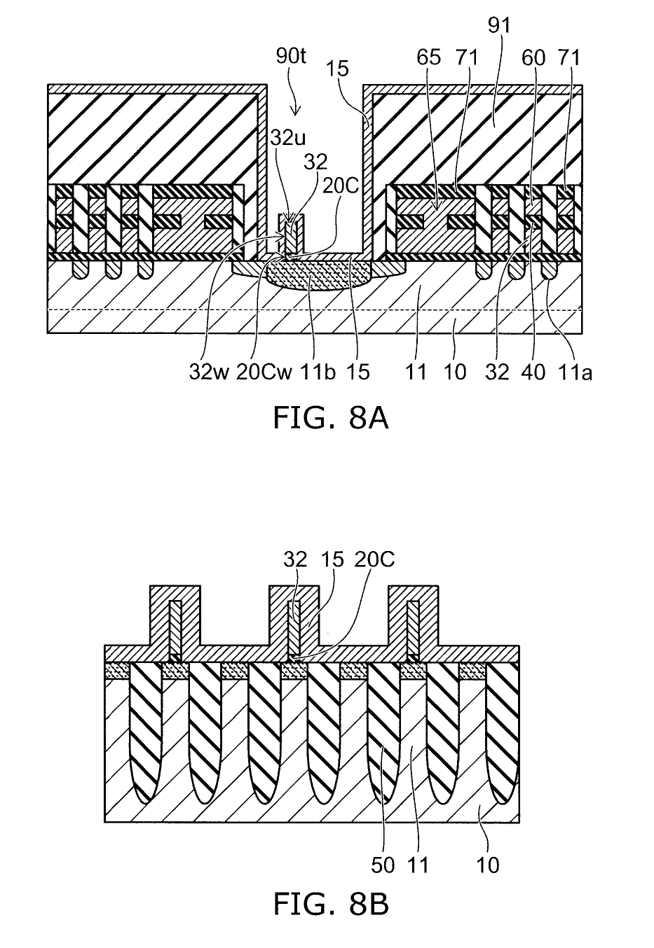

Next, the mask layer 90 is removed. Then, as shown in FIGS. 8A and 8B, a mask layer 91 made of resist is newly patterned. By sputtering film formation, a conductive film 15 is formed in the trench 90t and on the upper surface and the side surface of the mask layer 91. The thickness of the conductive film 15 is e.g. 15 nm or less. In the trench 90t, the conductive film 15 is in contact with the upper end 32u and the sidewall 32w of the semiconductor-containing layer 32 and the sidewall 20Cw of the insulating film 20C, and in contact with the semiconductor region 11.

Furthermore, the semiconductor region 11 in contact with the conductive film 15 is previously doped with impurity by ion implantation so that the impurity concentration of the diffusion region 11b is set higher. Thus, the conductive film 15 and the semiconductor region 11 are reliably connected by ohmic contact.

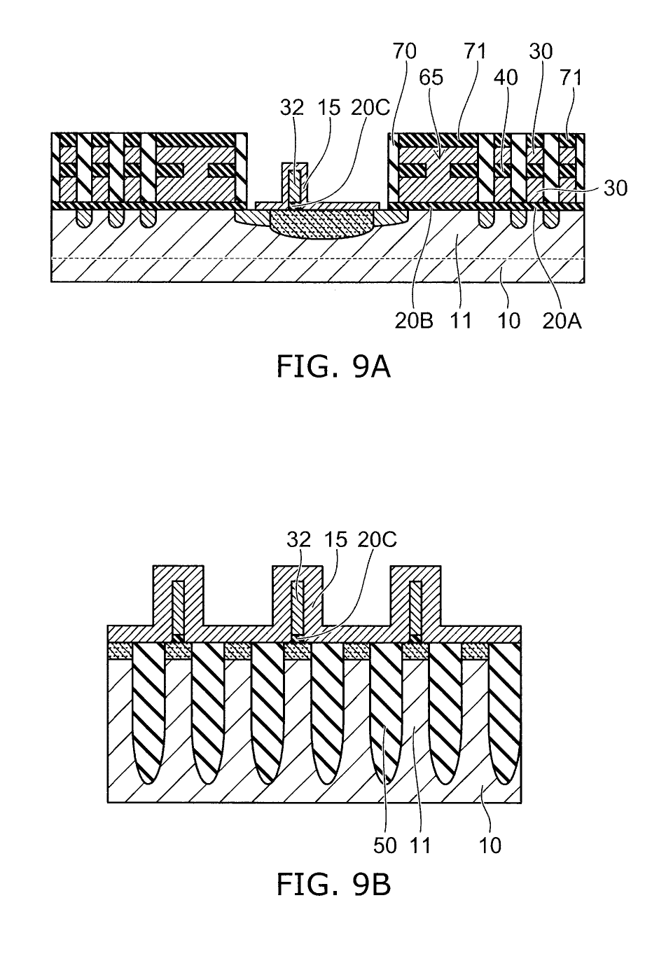

Next, as shown in FIGS. 9A and 9B, lift-off is performed. Thus, the conductive film 15 in contact with the mask layer 91 is removed with the mask layer 91.

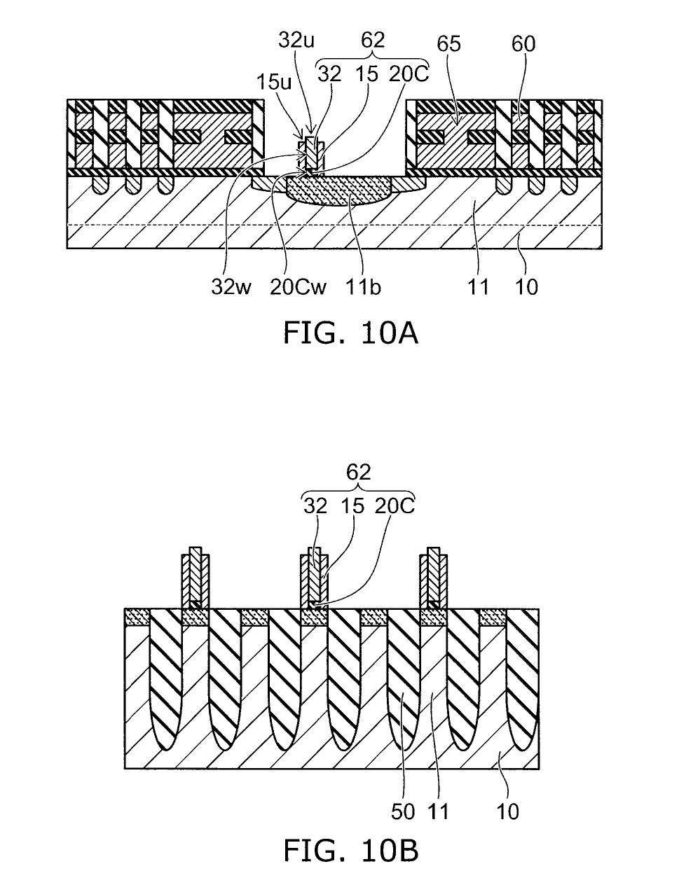

Next, as shown in FIGS. 10A and 10B, by dry etching, the conductive film 15 is etched. In this etching, the conductive film 15 is etched so that the upper end 32u of the semiconductor-containing layer 32 is projected upward from the upper end 15u of the conductive film 15. Furthermore, the conductive film 15 on the semiconductor region 11 is removed while leaving the conductive film 15 in contact with the sidewall 32w of the semiconductor-containing layer 32 and the sidewall 20Cw of the insulating film 20C.

Thus, a conductive structural body 62 including the insulating film 20C, the semiconductor-containing layer 32, and the conductive film 15 is formed on the semiconductor region 11.

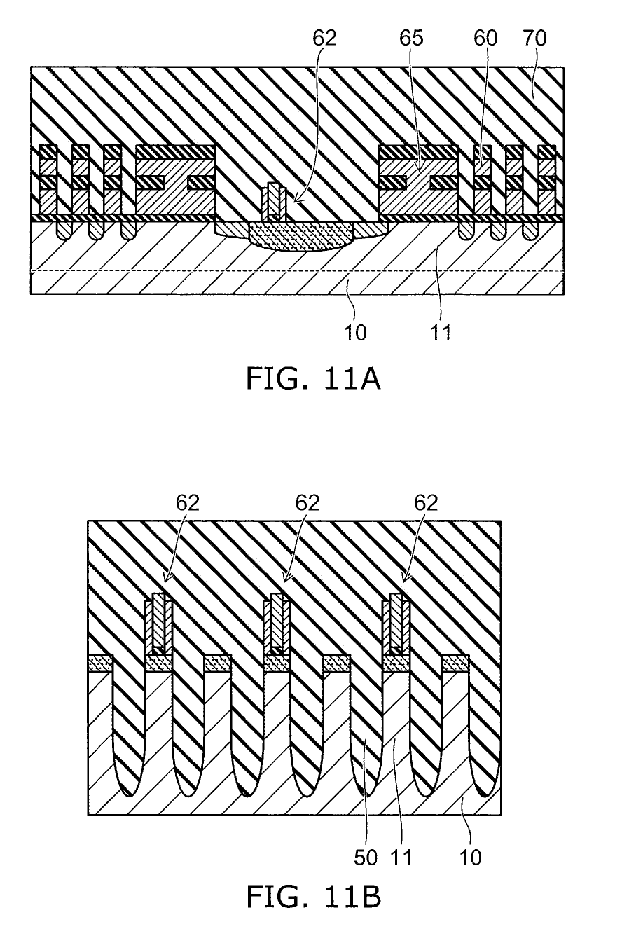

Next, as shown in FIGS. 11A and 11B, an interlayer insulating film 70 is formed again to obtain a state in which the conductive structural body 62 is covered with the interlayer insulating film 70.

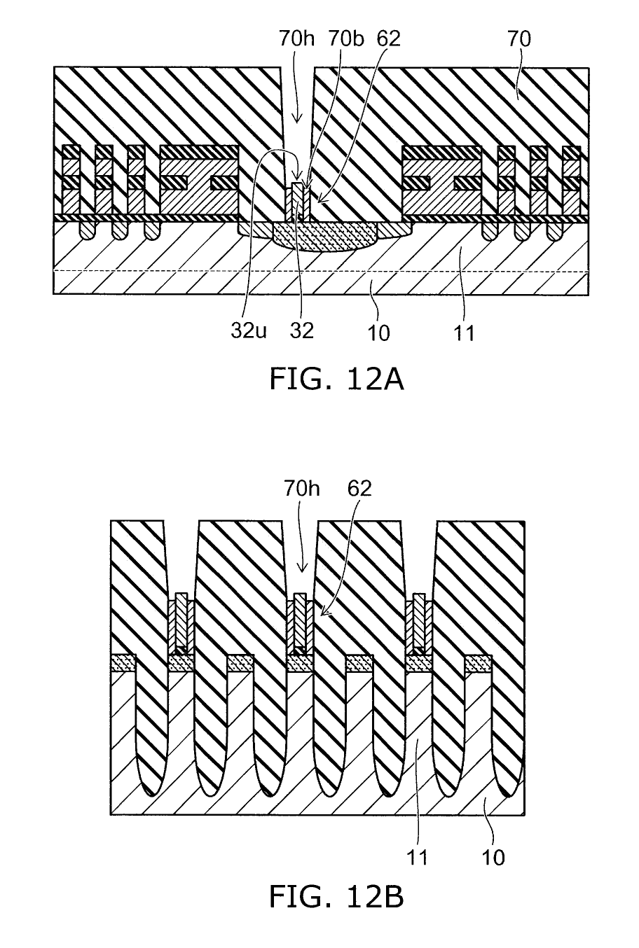

Next, as shown in FIGS. 12A and 12B, by RIE, a contact hole 70h extending from the surface of the interlayer insulating film 70 to the conductive structural body 62 is formed.

For instance, in order to ensure the contact between the conductive structural body 62 and the contact electrode 72 embedded in the contact hole 70h, the bottom 70b of the contact hole 70h is adjusted to be lower than the upper end of the conductive structural body 62 (upper end 32u of the semiconductor-containing layer 32).

Subsequently, in the contact hole 70h, a contact electrode 72 in contact with the conductive structural body 62 is formed (FIGS. 2A and 2B).

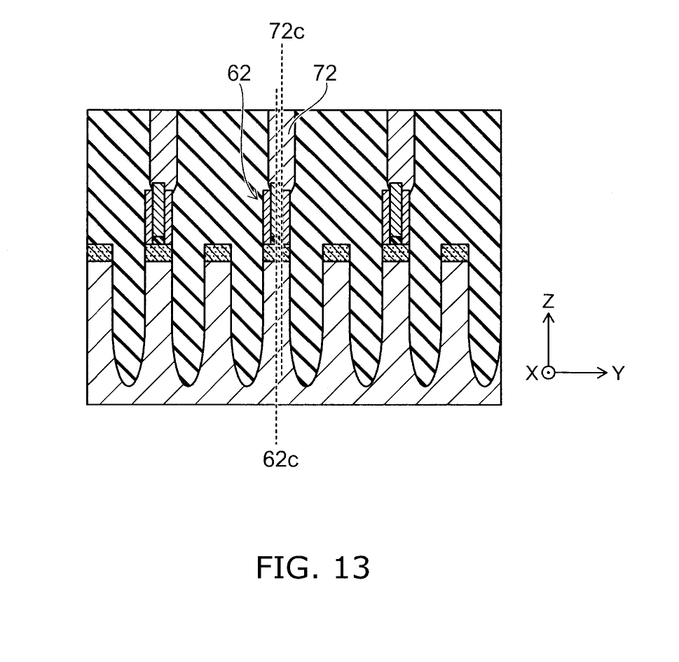

In the process, misalignment may occur between the central axis of the contact hole 70h and the central axis 62c of the conductive structural body 62. In such cases, as shown in FIG. 13, misalignment occurs between the central axis 72c of the contact electrode 72 and the central axis 62c of the conductive structural body 62. Such structure is also encompassed in this embodiment.

If the contact electrode 72 is directly connected to the semiconductor region 11 without the intermediary of the conductive structural body 62, the following problems occur.

For instance, with the progress of miniaturization of the nonvolatile semiconductor memory device, besides the semiconductor region 11 in contact with the contact electrode 72, the contact electrode 72 is also easily in contact with the semiconductor region 11 located adjacent to the former semiconductor region 11. In particular, in the case where misalignment occurs between the contact hole 70h and the semiconductor region 11, the probability of this contact (electrical short circuit) increases.

In the context of the progress of miniaturization of the nonvolatile semiconductor memory device, an effective approach for avoiding contact between the adjacent contact electrodes 72 is to alternately arrange the contact electrodes 72 as shown in FIG. 1. However, this approach does not solve the problem of the contact electrode 72 being in contact with the semiconductor region 11 adjacent to the semiconductor region 11 in contact with the contact electrode 72.

Another approach is to form the contact hole 70h with a narrower width. However, in this approach, the width of the contact electrode 72 is also made narrower. This induces the resistance increase of the contact electrode 72. Furthermore, the narrower width of the contact electrode 72 decreases the current flowing in the semiconductor region 11, or induces open failure between the contact electrode 72 and the semiconductor region 11.

In contrast, according to this embodiment, the contact electrode 72 is connected to the semiconductor region 11 via the conductive structural body 62. That is, the site where the contact electrode 72 is electrically connected to the semiconductor region 11 is locally projected by the conductive structural body 62.

In such structure, even if the miniaturization of the nonvolatile semiconductor memory device proceeds, the contact electrode 72 is not easily in contact with the semiconductor region 11 located adjacent to the semiconductor region 11 in contact with the contact electrode 72. This is because the distance between the contact electrode 72 and the semiconductor region 11 located adjacent to the semiconductor region 11 in contact with the contact electrode 72 is made farther by the interposition of the conductive structural body 62.

Furthermore, even if misalignment occurs between the contact hole 70h and the semiconductor region 11, the contact electrode 72 is not easily in contact with the semiconductor region 11 located adjacent to the semiconductor region 11 in contact with the contact electrode 72 by the interposition of the conductive structural body 62. That is, the manufacturing yield is improved.

Furthermore, there is no need to narrow the width of the contact hole 70h. Thus, the width of the contact electrode 72 is not narrowed. This can suppress the resistance increase of the contact electrode 72. Furthermore, because the width of the contact electrode 72 is not narrowed, there is no decrease of the current flowing in the semiconductor region 11, or no open failure between the contact electrode 72 and the semiconductor region 11.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

As described above, the charge accumulation layer is not limited to the floating gate layer, but may be a silicon nitride film in a MONOS structure. In this case, from the state of FIGS. 5A and 5B, the etching condition is changed, and etching is continued so as to leave the metal-containing layer 63 in the structural body 62L. Then, for instance, by chemical etching, the width in the X-direction and the Y-direction of the metal-containing layer 63, the insulating film 42, the silicon nitride film, and the insulating film 20C constituting the MONOS structure is reduced. Subsequently, by a process similar to the process from FIGS. 8A and 8B, a conductive structural body including a conductive film 15 in contact with the sidewall of the metal-containing layer 63, the insulating film 42, the silicon nitride film, and the insulating film 20C is formed on the semiconductor region 11. As an example, the conductive structural body of such structure can also achieve an effect similar to that described above.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device comprising:
a plurality of semiconductor regions extending in a first direction and arranged in a second direction crossing the first direction;
a plurality of control gate electrodes provided above the plurality of semiconductor regions, the control gate electrodes extending in the second direction, and the control gate electrodes arranged in the first direction;
a charge accumulation layer provided at a crossing position of each of the plurality of semiconductor regions and each of the plurality of control gate electrodes;
a first insulating film provided between the charge accumulation layer and each of the plurality of semiconductor regions;
a second insulating film provided between the charge accumulation layer and each of the plurality of control gate electrodes;
a select gate electrode provided on the plurality of semiconductor regions via a third insulating film, the select gate electrode extending in the second direction, and the select gate electrode located at an end of the arranged plurality of control gate electrodes;
a conductive structural body located on opposite side of the select gate electrode from the plurality of control gate electrodes, the conductive structural body provided on each of the plurality of semiconductor regions, and the conductive structural body including a fourth insulating film, a semiconductor-containing layer provided on the fourth insulating film, and a conductive film in contact with a sidewall of the fourth insulating film and a sidewall of the semiconductor-containing layer; and
a contact electrode extending in a third direction from a side of the plurality of semiconductor regions to a side of the plurality of control gate electrodes, and the contact electrode connected to the conductive structural body.

2. The device according to claim 1, wherein length from the semiconductor region to an upper end of the semiconductor-containing layer is longer than length from the semiconductor region to an upper end of the conductive film.

3. The device according to claim 1, wherein the conductive film includes at least one of tungsten, molybdenum, tantalum, titanium, nickel, and cobalt.

4. The device according to claim 1, wherein material of the semiconductor-containing layer and material of the charge accumulation layer are same.

5. The device according to claim 1, wherein material of the first insulating film and material of the fourth insulating film are same.

6. The device according to claim 1, wherein central axis of the contact electrode and central axis of the conductive structural body are misaligned.

7. A method for manufacturing a nonvolatile semiconductor memory device, comprising:
(a) forming a structural body including a plurality of semiconductor regions extending in a first direction and arranged in a second direction crossing the first direction, a plurality of control gate electrodes provided above the plurality of semiconductor regions, extending in the second direction, and arranged in the first direction, a charge accumulation layer provided at a crossing position of each of the plurality of semiconductor regions and each of the plurality of control gate electrodes, a first insulating film provided between the charge accumulation layer and each of the plurality of semiconductor regions, a second insulating film provided between the charge accumulation layer and each of the plurality of control gate electrodes, and a select gate electrode provided on the plurality of semiconductor regions via a third insulating film, extending in the second direction, and located at an end of the arranged plurality of control gate electrodes, and forming a semiconductor-containing layer via a fourth insulating film on each of the plurality of semiconductor regions on opposite side of the select gate electrode from the plurality of control gate electrodes;
(b) reducing width in the first direction and the second direction of the semiconductor-containing layer;
(c) forming a conductive film in contact with each of the plurality of semiconductor regions and in contact with a sidewall of the fourth insulating film and a sidewall of the semiconductor-containing layer;
(d) forming a conductive structural body including the fourth insulating film, the semiconductor-containing layer, and the conductive film, and forming an interlayer insulating film covering the conductive structural body;
(e) forming a contact hole extending from a surface of the interlayer insulating film to the conductive structural body; and
(f) forming a contact electrode in contact with the conductive structural body in the contact hole.

8. The method according to claim 7, wherein in the step (b), width of the semiconductor-containing layer in the second direction is made narrower than width of the semiconductor region in the second direction.

9. The method according to claim 7, wherein in the step (c), each of the plurality of semiconductor regions in contact with the conductive film is doped with impurity.

10. The method according to claim 7, wherein in the step (e), the contact hole is formed so that bottom of the contact hole is lower than upper end of the conductive structural body.
